(19) United States
(12) Patent Application Publication
(10) Pub. No.: US 2016/0171396 A1
(43) Pub. Date: Jun. 16, 2016

(54) MODIFICATION AND DISPLAY OF BUSINESS MODELS

(71) Applicant: International Business Machines Corporation, Armonk, NY (US)

(72) Inventors: Rajesh Kalyanaraman, Bangalore (IN); Badrinarayan Ravichandran, Bangalore (IN)

(21) Appl. No.: 14/571,822

(22) Filed: Dec. 16, 2014

(51) Int. Cl. G06Q 10/06; G06F 17/50

(52) U.S. Cl. CPC G06Q 10/067; G06F 17/50

(57) ABSTRACT

An original business model is received. At least one modification to the original business model is received. The original business model and the at least one modification to the original business model is caused to be displayed. An indication of an acceptance or a rejection for reach modification of the at least one modification to the original business model is received.

### BACKGROUND OF THE INVENTION

The present invention relates generally to the field of business process modeling and notation (BPMN), and more particularly to visual representation of cost and critical path analysis for BPMN models and diagrams.

Business process modeling and notation is a standard for business process modeling that provides a graphical notation for specifying business processes in a business process diagram (BPD). The objective of BPMN is to support business process management, for both technical users and business users, by providing a notation that is intuitive to business users, yet able to represent complex process semantics. For example, business process modeling and notation is used to model a business process using appropriate processes like tasks, call activities, gateways, etc. The flow in the business model is represented by flow connectors like sequence flows, message flows, data associations, etc. Each of the elements in a BPD, for example a task, has some element associated with it in terms of time to complete the task, cost to complete the task, etc. The individual elements contribute to overall costs of the process. Critical paths are identified based on the cost of the individual elements and the flow connectors.

The primary goal of BPMN is to provide a standard notation readily understandable by all business stakeholders. These include the business analyst, who create and refine the processes, the technical developers responsible for implementing them, and the business managers, who monitor and manage them. Consequently, BPMN serves as a common language, bridging the communication gap that frequently occurs between business process design and implementation.

### SUMMARY

Embodiments of the present invention include a method, computer program product, and system for modifying a business model. In one embodiment, an original business model is received. At least one modification to the original business model is received. The original business model and the at least one modification to the original business model is caused to be displayed. An indication of an acceptance or a rejection for each modification of the at least one modification to the original business model is received.

### BRIEF DESCRIPTION OF THE DRAWINGS

FIG. 1 is a functional block diagram of a data processing environment, in accordance with an embodiment of the present invention;

FIG. 2 is a flowchart depicting operational steps of a program to display modifications to a business model, in accordance with an embodiment of the present invention;

FIG. 3A is a visual representation of an exemplary original business model, in accordance with an embodiment of the present invention;

FIG. 3B is a visual representation of the original business model displayed along with a proposed business model that is an alternative process to the original business model, in accordance with an embodiment of the present invention;

FIG. 3C is a visual representation of the original business model with an additional element after the first two elements, in accordance with an embodiment of the present invention;

FIG. 4 is a visual representation of a business model, in accordance with an embodiment of the present invention; and

FIG. 5 depicts a block diagram of components of a computing system representative of the computer of FIG. 1, in accordance with an embodiment of the present invention.

### DETAILED DESCRIPTION

Embodiments of the present invention allow for the modifications to a business model. First, an original business model is received. The original business model consists of at least one element and at least one flow. Next, one or more modifications to the original business model are received. Next, the original model and the modifications to the original business model are displayed. Finally, each of the modifications may be accepted or rejected and a proposed business model that includes the accepted modifications may be displayed.

Some embodiments of the present invention recognize that business process modeling has a need for the following: (i) the total cost to be updated when modifications to the business model are made; (ii) a view that highlights the costs per element and budgeted costs versus total costs; (iii) a view to highlight the critical path in the business model; (iv) a view that highlights how individual task modifications can affect the overall cost of the original business model; (v) a view that will warn a user when modifications in the critical path occur due to addition or deletion of an element; and (vi) a warning to indicate when the total cost exceeds the budgeted cost.

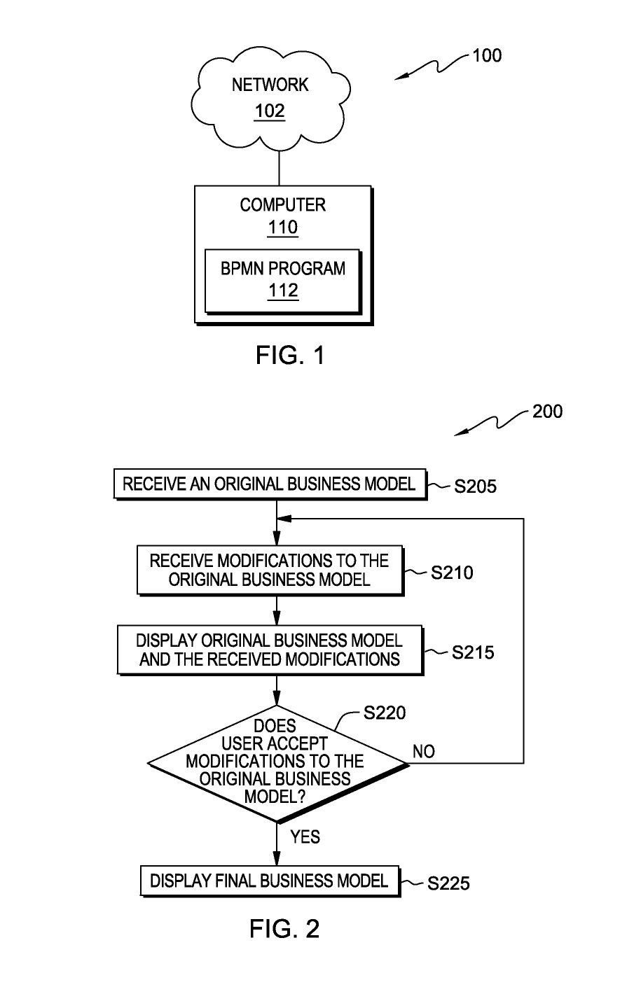

The present invention will now be described in detail with reference to the Figures. FIG. 1 is a functional block diagram illustrating a data processing environment, generally designated 100, in accordance with an embodiment of the present invention. FIG. 1 provides only an illustration of one implementation and does not imply any limitations with regard to the systems and environments in which different embodiments may be implemented. Many modifications to the depicted embodiment may be made by those skilled in the art without departing from the scope of the invention as recited by the claims.

An embodiment of data processing environment 100 includes computer 110, connected to network 102. Network 102 can be, for example, a local area network (LAN), a telecommunications network, a wide area network (WAN) such as the Internet, or any combination of the three, and include wired, wireless, or fiber optic connections. In general, network 102 can be any combination of connections and protocols that will support communications between computer 110 and any other computing device connected to network 102, in accordance with embodiments of the present invention.

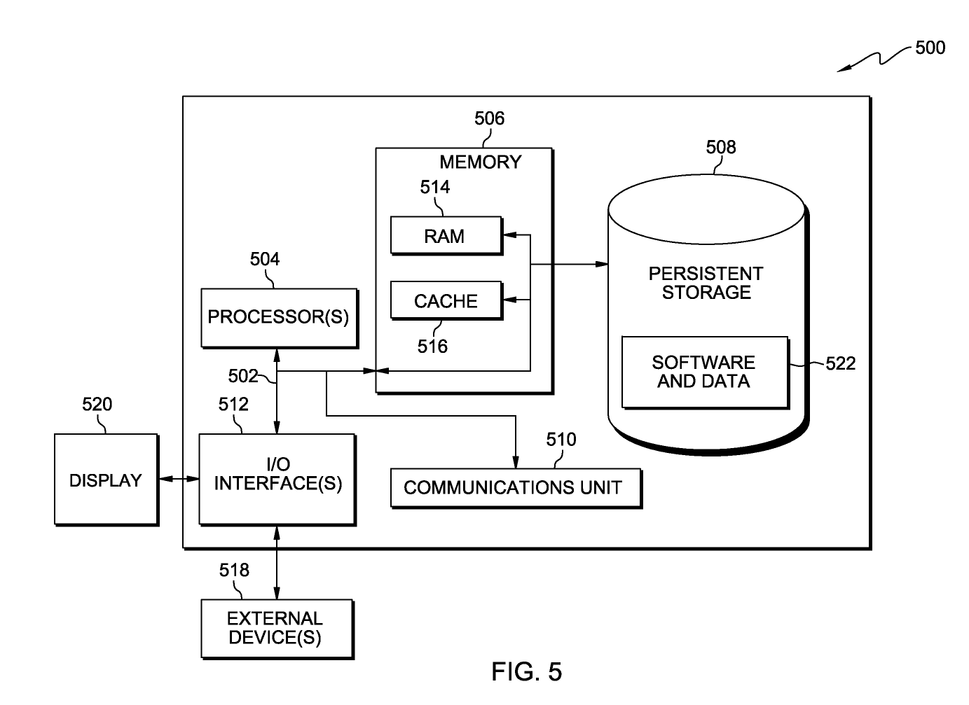

In example embodiments, computer 110 may be a laptop, tablet, or netbook personal computer (PC), a desktop computer, a personal digital assistant (PDA), a smart phone, or any programmable electronic device capable of communicating with any computing device within data processing environment 100. In certain embodiments, computer 110 collectively represents a computer system utilizing clustered computers and components (e.g., database server computers, application server computers, etc.) that act as a single pool of seamless resources when accessed by elements of data processing environment 100, such as in a cloud computing environment. In general, computer 110 is representative of any electronic device or combination of electronic devices capable of executing computer readable program instructions. Computer 110 may include components as depicted and described in further detail with respect to computer 500 in FIG. 5, in accordance with embodiments of the present invention.

Computer 110 includes BPMN program 112. In an embodiment, BPMN program 112 is a program, application, or subprogram of a larger program that performs business process modeling operations on computer 110. In an embodiment, BPMN program 112 is integrated into traditional business process modeling software, known in the art, to perform modifications to the original programs business process modeling operations.

In an embodiment, BPMN program 112 receives an original business model. BPMN program 112 receives modifications to the original business model. For example, a user can change one of the paths in the business model to provide two alternative business models. BPMN program 112 displays the original business model alongside the modified business model that includes the modifications. In an alternative embodiment, BPMN program 112 displays only a modified business model that has both the original business model and the modifications included. BPMN program 112 may ask the user if they would like to accept the modifications to the business model. In an embodiment, BPMN program 112 asks the user if they would like to accept or reject all of the modifications. In an alternative embodiment, BPMN program 112 asks the user if they would like to accept or reject each individual modification so that the user may accept some modification and reject others. During the accept/reject process, the user is notified, via a warning, by BPMN program 112 of certain modifications that may cause issues with the budget, timing, critical path, etc. BPMN program 112 displays the final business model that includes the accepted modifications to the business model.

A user interface (not shown) is a program that provides an interface between a user and BPMN program 112. A user interface refers to the information (such as graphic, text, and sound) a program present to a user and the control sequences the user employs to control the program. There are many types of user interfaces. In one embodiment, the user interface may be a graphical user interface (GUI). A GUI is a type of user interface that allows users to interact with electronic devices, such as a keyboard and mouse, through graphical icons and visual indicators, such as secondary notations, as opposed to text-based interfaces, typed command labels, or text navigation. In computers, GUIs were introduced in reaction to the perceived steep learning curve of command-line interfaces, which required commands to be typed on the keyboard. The actions in GUIs are often performed through direct manipulation of the graphics elements.

FIG. 2 is a flowchart of workflow 200 depicting operational steps for presentation of business models on computer 110 based on modifications to an original business model and providing warnings to critical paths, timing, budgets, etc., due to the modifications to elements or flows, in accordance with an embodiment of the present invention. In one embodiment, the steps of the workflow are performed by BPMN program 112. Alternatively, steps of the workflow can be performed by any other program while working with BPMN program 112. In a preferred embodiment, a user, via a user interface discussed previously, can invoke workflow 200 upon determining that they would like to work on a business model. In an alternative embodiment, workflow 200 can be invoked automatically under the control of another program, for example, upon the user clicking on a button in a separate business processing modeling and notation software, the BPMN program 112 begins a step in workflow 200.

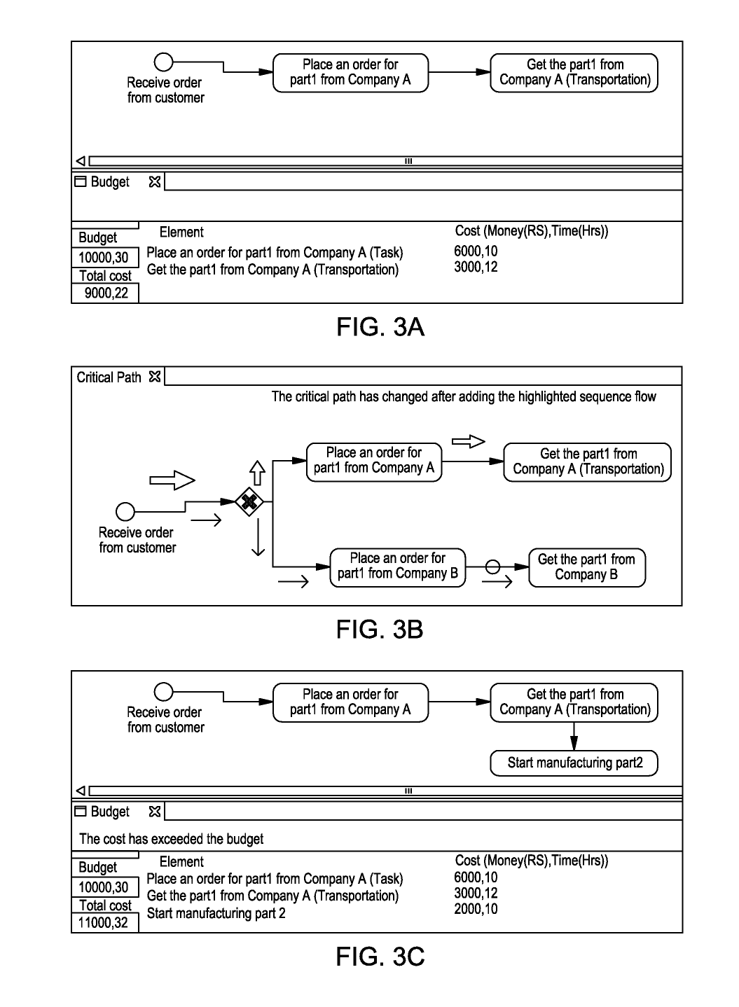

BPMN program 112 receives an original business model (step S205). In an embodiment, a user, using user interface discussed previously, creates an original business model using BPMN program 112. In an alternative embodiment, a previously created business model can be imported into BPMN program 112. In yet another embodiment, a business model can be created in another business processing model and notation software and BPMN program 112 can access and receive it. For example, as shown in FIG. 3A, a received original business model is depicted with three elements. The first element is “Receive order from customer.” In the order from the customer, a budget of 10,000 Indian Rupees (Rs), 30 work hours is indicated, and the order is for “part1”. The second element is “Place an order for part1 from Company A”. In the placed order, “part1” costs 6,000 Rs and 10 hours of labor. The third element is “Get the part1 from Company A (Transportation)”. In the transportation of part1, transportation costs 3,000 Rs and 12 hours of labor. The total cost of the business model is 9,000 Rs and 22 hours of labor. The total budget for the business model is 10,000 Rs and 30 hours of labor.

BPMN program 112 receives modifications to the original business model (step S210). In an embodiment, a user, using user interface discussed previously, indicates modifications to the original business model using BPMN program 112. In an alternative embodiment, a second business model can be imported into BPMN program 112 and the second business model includes modifications to the original business model. The modifications, when incorporated to the original business model, create the proposed business model. In an embodiment, the modification received can be a new element or flow in the business model. In other words, element A and B are already in the business model and element C is received that occurs after element A and B. In an alternative embodiment, the modification received can be an alternative or change to an element or flow currently in the business model. In other words, elements A1 and B1 are already in the business model and element B2 is received that is an alternative to element B1 and element B2 occurs after process A1. In yet another embodiment, the modification received can be the removal of an element or flow currently in the business model.

BPMN program 112 displays the original business model and the received modifications (step S215). In an embodiment, BPMN program 112 displays the original business model together with the modified business model that includes the modifications. For example, as shown in FIG. 3B, the original business model is displayed along with a proposed business model that is an alternative process to the original business model. FIG. 3B includes “Place an order for part1 from Company B”, which is an alternative element to “Place an order for part1 from Company A” as shown in FIGS. 3A and 3B. In another example (not shown), BPMN program 112 may display the original business model in a first view and the modified business model that includes the modifications in a second view. In an alternative embodiment, BPMN program 112 displays only a modified business model that has both the original business model and the modifications included. In another example, as shown in FIG. 3C, the original business model is displayed with an additional element after the first two elements. FIG. 3C includes “Start manufacturing part2”, which is the next element in the business model after “Get the part1 from Company A (Transportation).” In the “starting manufacturing part2” element, the cost is 2,000 Rs and 10 hours of labor. The total cost is now 11,000 Rs, which is over the budget of 10,000 Rs. Additionally, the total hours of labor is 32, which is now over the budget of 30 hours. In an embodiment, the business model may include a warning when the budget is exceeded. For example, “The budget for hours of labor is now 32 hours and that exceeds the budget of 30 hours by 2 hours.” A fatter arrow can indicate an original business model and a thinner arrow can indicate the proposed business model or highlighted business model. In this example, the highlighted sequence flow is the lower sequence flow. In an embodiment, the business model may include a warning when the critical path changes. For example, “The critical path has changed after adding the highlighted sequence flow” is displayed.

In an embodiment, as show in FIG. 3A, a view is shown that is a “budget view.” The budget view shows the cost of the individual elements and flows and also may have a warning when the total cost exceeds the budget. Additionally, there may be a warning for any other items that exceed the budget, for example hours of labor. The user can add or delete elements or flows from the diagram. The cost of the process is already available as a part of the documentation of the element or flow or predefined in BPMN program 112. The budget view is updated when an element or flow is added or deleted and the cost is updated accordingly. The budget view also shows the total cost of the business model including all elements and flows after the addition or deletion of processes. As shown in FIG. 3C, also a “budget view,” shows a warning because the total cost exceeds the budget.

In an alternative embodiment, as shown in FIG. 3B, a “critical path view” is shown. A critical path view shows the critical path in the business model, as calculated through critical path algorithms, known in the art, and would be updated as individual elements or flows are added or deleted. A critical path arrow, the larger arrow, can show the present critical path in the process, in other words the original business model. As a user adds or deletes a process or adds or deletes a flow connector from the business model, the critical path can change and can be updated accordingly, as shown by the thinner arrow, or the proposed business model. If the critical path changes a warning may be indicated to the user, as shown and discussed previously.

BPMN program 112 determines if the user accepts modifications to the original business model (decision block S220). BPMN program 112 receives an indication from a user to accept or reject at least one of the modifications, via the GUI of BPMN program 112, discussed previously. In an embodiment, the user can accept or reject all business modifications as a whole. In other words, if there are three modifications to the business model, the user can accept all three or reject all three. In an alternative embodiment, the user can accept or reject each modification individually. In other words, if there are three modifications to the business model, the user can accept two of the modifications but still reject one of the modifications. In an embodiment, warning indications can be displayed when the acceptance or rejection of modifications can change the critical path or the budget is exceeded.

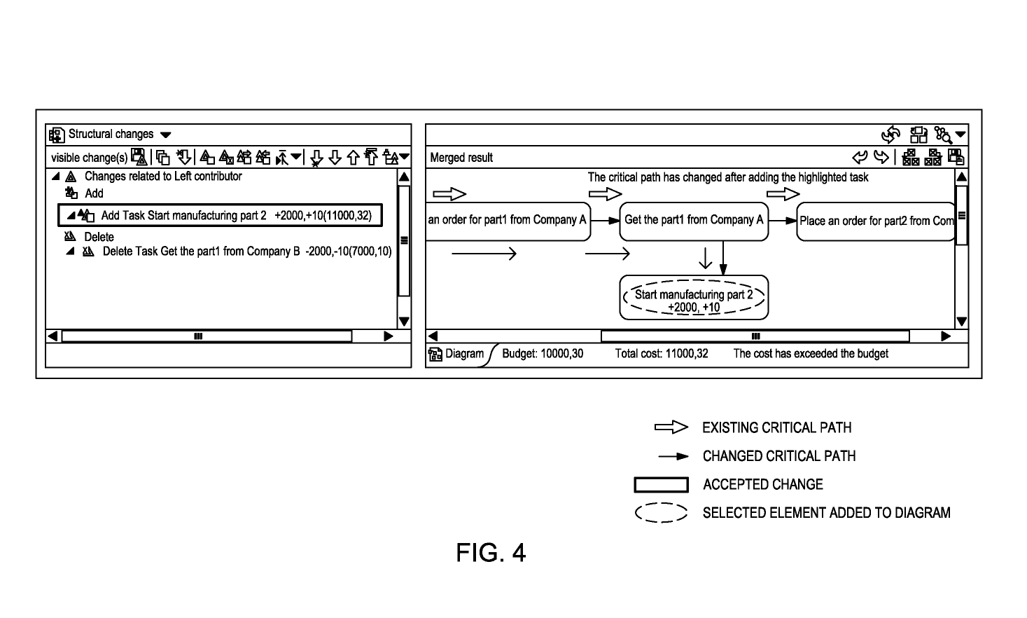

In an embodiment, as shown in FIG. 4, a “comparison view” is shown. The comparison view is used when differential cost and critical path analysis has to be done between two versions of the business model. The comparison view would show additional information in a merged result regarding the cost and critical path changes. As shown in FIG. 4, the circled element “Start manufacturing part A” is the selected process to be added to the original business model. In other words, this is the modification to the business model. On the side of the diagram, the user has the option to add the element “Start manufacturing part A” and delete the element “Get the part1 from Company B”. The existing critical path is shown by the larger arrow. The changed critical path is shown by the thinner arrow. The box indicates the accepted change which is to add the process “Start manufacturing part A”. The changes to the budget and hours are shown as well. Additionally, as shown in the bottom right, there is a warning indication that “The cost has exceeded the budget” due to the change. In an alternative embodiment, this warning indication may be a window that is separate from the diagram to give more emphasis to the user about the issue in the business model. In yet another alternative embodiment, a warning indication can occur when the critical path changes.

If the user does not accept any of the modifications to the business model (decision block S220, no branch), then BPMN program 112 receives more modifications to the original business model (step S210). In an alternative embodiment, the user may accept two of the modifications and reject one of the modifications, as discussed above, and since the user accepted at least one of the modifications, BPMN program 112 can ask the user if they would like have the final business model displayed. If the user indicates that they would like the final business model displayed then BPMN program 112 will proceed to display the final business model (Step S225), which includes the accepted modifications. Alternatively, BPMN program 112 can ask the user if they would like to include more modifications and proceed to receive more modification to the original business model (step S210). If the user accepts all of the modifications (decision block S220, yes branch), BPMN program displays the final business model (Step S225), which includes the modifications.

FIG. 5 depicts a block diagram of components of computer 500 which is representative of computer 110, in accordance with an illustrative embodiment of the present invention. It should be appreciated that FIG. 5 provides only an illustration of one implementation and does not imply any limitations with regard to the environments in which different embodiments may be implemented. Many modifications to the depicted environment may be made.

Computer 500 includes communications fabric 502, which provides communications between computer processor(s) 504, memory 506, persistent storage 508, communications unit 510, and input/output (I/O) interface(s) 512. Communications fabric 502 can be implemented with any architecture designed for passing data and/or control information between processors (such as microprocessors, communications and network processors, etc.), system memory, peripheral devices, and any other hardware components within a system. For example, communications fabric 502 can be implemented with one or more buses.

Memory 506 and persistent storage 508 are computer readable storage media. In this embodiment, memory 506 includes random access memory (RAM) 514 and cache memory 516. In general, memory 506 can include any suitable volatile or non-volatile computer readable storage media. Software and data 522 are stored in persistent storage 508 for access and/or execution by processors 504 via one or more memories of memory 506. With respect to computer 110, software and data 522 includes BPMN program 112.

In this embodiment, persistent storage 508 includes a magnetic hard disk drive. Alternatively, or in addition to a magnetic hard disk drive, persistent storage 508 can include a solid state hard drive, a semiconductor storage device, read-only memory (ROM), erasable programmable read-only memory (EPROM), flash memory, or any other computer readable storage media that is capable of storing program instructions or digital information.

The media used by persistent storage 508 may also be removable. For example, a removable hard drive may be used for persistent storage 508. Other examples include optical and magnetic disks, thumb drives, and smart cards that are inserted into a drive for transfer onto another computer readable storage medium that is also part of persistent storage 508.

Communications unit 510, in these examples, provides for communications with other data processing systems or devices. In these examples, communications unit 510 may include one or more network interface cards. Communications unit 510 may provide communications through the use of either or both physical and wireless communications links. Software and data 522 may be downloaded to persistent storage 508 through communications unit 510.

I/O interface(s) 512 allows for input and output of data with other devices that may be connected to computer 500. For example, I/O interface 512 may provide a connection to external devices 518 such as a keyboard, keypad, a touch screen, and/or some other suitable input device. External devices 518 can also include portable computer readable storage media such as, for example, thumb drives, portable optical or magnetic disks, and memory cards. Software and data used to practice embodiments of the present invention, e.g., BPMN program 112, can be stored on such portable computer readable storage media and can be loaded onto persistent storage 508 via I/O interface(s) 512. I/O interface(s) 512 also can connect to a display 520.

Display 520 provides a mechanism to display data to a user and may be, for example, a computer monitor. Display 520 can also function as a touch screen, such as a display of a tablet computer.

The programs described herein are identified based upon the application for which they are implemented in a specific embodiment of the invention. However, it should be appreciated that any particular program nomenclature herein is used merely for convenience, and thus the invention should not be limited to use solely in any specific application identified and/or implied by such nomenclature.

The present invention may be a system, a method, and/or a computer program product. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as, Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A method for modifying a business model, the method comprising:
receiving, by one or more computer processors, an original business model;
receiving, by one or more computer processors, at least one modification to the original business model;
causing, by one or more computer processors, the original business model and the at least one modification to the original business model to be displayed; and
receiving, by one or more computer processors, an indication of an acceptance or a rejection for each modification of the at least one modification to the original business model.

2. The method of claim 1, further comprising:
causing, by one or more computer processors, the original business model and a proposed business model to be displayed, wherein the proposed business model includes modifications to the original business model that have been indicated as accepted.

3. The method of claim 1, further comprising:
receiving, by one or more computer processors, a critical path of the original business model;
receiving, by one or more computer processors, a budget of the original business model;
determining, by one or more computer processors, whether at least one of the acceptance or rejections indicated for each modification of the at least one modification to the original business model causes a change in the critical path of the original business model or the budget to be exceeded of the original business model; and
responsive to determining whether at least one of the acceptance or rejections indicated for each modification of the at least one modification to the original business model causes a change in the critical path for the original business model or the budget to be exceeded of the original business model, causing, by one or more computer processors, a warning to be displayed indicating a change in the critical path of the original business model or the budget being exceeded of the original business model.

4. The method of claim 1, wherein the at least one modification to the original business model is one or more of the following: a modification to an a flow in the original business model, a modification to an element in the original business model, a new flow in the original business model, a new element in the original business model, removal of a flow from the original business model, or removal of an element from the original business model.

5. The method of claim 3, further comprising:
causing, by one or more computer processors, the original business model and a proposed business model to be displayed together in a budget view, wherein the budget view displays the budget of the original business model, displays a cost of all elements and flows in the original business model, displays a cost of all elements and flows in the proposed business model, and displays a cost of the proposed business model, wherein the cost is one or more of the following: financial or hours.

6. The method of claim 3, further comprising:
causing, by one or more computer processors, the original business model and a proposed business model to be displayed together in a critical path view, wherein the critical path view displays a critical path of the original business model, a critical path of the proposed business model, and any changes to the critical path due to the acceptance or rejections indicated for each modification of the at least one modification to the original business model.

7. A computer program product for modifying a business model, the computer program product comprising:
one or more computer readable storage media and program instructions stored on the one or more computer readable storage media, the program instructions comprising:
program instructions to receive an original business model;
program instructions to receive at least one modification to the original business model;
program instructions to cause the original business model and the at least one modification to the original business model to be displayed; and
program instructions to receive an indication of an acceptance or a rejection for each modification of the at least one modification to the original business model.

8. The computer program product of claim 7, further comprising program instructions, stored on the one or more computer readable storage media, to:
cause the original business model and a proposed business model to be displayed, wherein the proposed business model includes modifications to the original business model that have been indicated as accepted.

9. The computer program product of claim 7, further comprising program instructions, stored on the one or more computer readable storage media, to:
receive a critical path of the original business model;
receive a budget of the original business model;
determine whether at least one of the acceptance or rejections indicated for each modification of the at least one modification to the original business model causes a change in the critical path of the original business model or the budge to be exceeded of the original business model; and
responsive to determining whether at least one of the acceptance or rejections indicated for each modification of the at least one modification to the original business model causes a change in the critical path of the original business model or the budge to be exceeded of the original business model cause a warning to be displayed indicating a change in the critical path of the original business model or the budget being exceeded of the original business model.

10. The computer program product of claim 7, wherein the at least one modification to the original business model is one or more of the following: a modification to an a flow in the original business model, a modification to an element in the original business model, a new flow in the original business model, a new element in the original business model, removal of a flow from the original business model, or removal of an element from the original business model.

11. The computer program product of claim 9, further comprising program instructions, stored on the one or more computer readable storage media, to:
cause the original business model and a proposed business model to be displayed together in a budget view, wherein the budget view displays the budget of the original business model, displays a cost of all elements and flows in the original business model, displays a cost of all elements and flows in the proposed business model, and displays a cost of the proposed business model, wherein the cost is one or more of the following: financial or hours.

12. The computer program product of claim 9, further comprising program instructions stored on the one or more computer readable storage media, to:
cause the original business model and a proposed business model to be displayed together in a critical path view, wherein the critical path view displays a critical path of the original business model, a critical path of the proposed business model, and any changes to the critical path due to the acceptance or rejections indicated for each modification of the at least one modification to the original business model.

13. A computer system for modifying a business model, the computer system comprising:
one or more computer processors;
one or more computer readable storage media; and
program instructions stored on the computer readable storage media for execution by at least one of the one or more processors, the program instructions comprising:
program instructions to receive an original business model;
program instructions to receive at least one modification to the original business model;
program instructions to cause the original business model and the at least one modification to the original business model to be displayed; and
program instructions to receive an indication of an acceptance or a rejection for each modification of the at least one modification to the original business model.

14. The computer system of claim 13, further comprising program instructions, stored on the one or more computer readable storage media for execution by the at least one of the one or more computer processors, to:
cause the original business model and a proposed business model to be displayed, wherein the proposed business model includes modifications to the original business model that have been indicated as accepted.

15. The computer system of claim 13, further comprising program instructions, stored on the one or more computer readable storage media for execution by the at least one of the one or more computer processors, to:
receive a critical path of the original business model;
receive a budget of the original business model;
determine whether at least one of the acceptance or rejections indicated for each modification of the at least one modification to the original business model causes a change in the critical path of the original business model or the budget to be exceeded of the original business model; and
responsive to determining whether at least one of the acceptance or rejections indicated for each modification of the at least one modification to the original business model causes a change in the critical path of the original business model or the budget to be exceeded of the original business model cause a warning to be displayed indicating a change in the critical path of the original business model or the budget being exceeded of the original business model.

16. The computer system of claim 13, wherein the at least one modification to the original business model is one or more of the following: a modification to an a flow in the original business model, a modification to an element in the original business model, a new flow in the original business model, a new element in the original business model, removal of a flow from the original business model, or removal of an element from the original business model.

17. The computer system of claim 15, further comprising program instructions, stored on the one or more computer readable storage media for execution by the at least one of the one or more computer processors, to:
cause the original business model and a proposed business model to be displayed together in a budget view, wherein the budget view displays the budget of the original business model, displays a cost of all elements and flows in the original business model, displays a cost of all elements and flows in the proposed business model, and displays a cost of the proposed business model, wherein the cost is one or more of the following: financial or hours.

18. The computer system of claim 15, further comprising program instructions, stored on the one or more computer readable storage media for execution by the at least one of the one or more computer processors, to:
cause the original business model and a proposed business model to be displayed together in a critical path view, wherein the critical path view displays a critical path of the original business model, a critical path of the proposed business model, and any changes to the critical path due to the acceptance or rejections indicated for each modification of the at least one modification to the original business model.
